(19) United States
(12) Patent Application Publication
(10) Pub. No.: US 2025/0300007 A1
(43) Pub. Date: Sep. 25, 2025

(54) PLASMA ASSISTED METAL OXIDE REDUCTION

(71) Applicant: Tokyo Electron Limited, Tokyo (JP)

(72) Inventors: Yu-Hao Tsai, Albany, NY (US); Hojin Kim, Albany, NY (US); Mingmei Wang, Albany, NY (US)

(21) Appl. No.: 18/611,527

(22) Filed: Mar. 20, 2024

(51) Int. Cl. H01L 21/768; H01J 37/32

(52) U.S. Cl. CPC H01L 21/76823; H01L 21/76814; H01L 21/76826; H01J 37/32082; H01J 2237/327; H01J 2237/338

(57) ABSTRACT

A method for making a semiconductor device can include providing a substrate having a metal layer therein, where an exposed surface of the metal layer includes a surface layer of oxidized metal, flowing carbon monoxide into a chamber containing the substrate and onto the surface layer, and reacting the carbon monoxide with the oxidized metal of the surface layer to form carbon dioxide and non-oxidized metal at the surface layer by removing oxygen from the oxidized metal of the surface layer, wherein a temperature in the chamber during the reacting is less than 40 degrees Celsius.

### TECHNICAL FIELD

The present disclosure relates generally to methods for manufacturing semiconductor devices, and more particularly, processes for metal oxide reduction for manufacturing semiconductor devices.

### BACKGROUND

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other.

Normally, each metal layer must form an electrical contact to at least one additional metal layer. Such electrical contact is achieved by etching a feature in the interlayer dielectric layer that separates the metal layers, and filling the resulting feature with a metal to create an interconnect. A “via” normally refers to any feature such as a hole, line, or other similar feature formed within a dielectric layer and filled with a metal plug that provides an electrical connection through the dielectric layer to a conductive layer underlying the dielectric layer. Similarly, metal layers connecting two or more vias are normally referred to as “trenches.”

Processes involving oxygen and/or exposure to ambient air can oxidize an exposed metal layer quickly, especially pure metals that are typically used for making conducting lines in semiconductor devices. After a chemical mechanical polishing (CMP) and subsequent cleaning after the CMP, an exposed metal layer is very sensitive to oxidation during transport and while in queue for subsequent processing. Even simply too much queue time while the metal layer has an exposed surface can quickly result in several monolayers of oxidized metal forming on the metal layer. Even a few monolayers of oxidized metal on the exposed surface of the metal layer can affect the electrical characteristics of the metal interconnect at the joining of metal conductors (at the interface), such as increased electrical resistance and/or parasitic capacitance. Thus, it is important to removal all traces of oxidized metal from an exposed surface of a metal layer before subsequent processing steps are performed to maintain high quality production and semiconductor device reliability.

### SUMMARY

In accordance with an embodiment of the present disclosure, a method for making a semiconductor device can include: providing a substrate having a metal layer therein, wherein an exposed surface of the metal layer includes a surface layer of oxidized metal; flowing carbon monoxide into a chamber containing the substrate and onto the surface layer; and reacting the carbon monoxide with the oxidized metal of the surface layer to form carbon dioxide and non-oxidized metal at the surface layer by removing oxygen from the oxidized metal of the surface layer, wherein a temperature in the chamber during the reacting is less than 40 degrees Celsius.

In accordance with an embodiment of the present disclosure, a method for making a semiconductor device can include: receiving a substrate having a metal layer therein, where an exposed surface of the metal layer includes a surface layer of oxidized metal; flowing carbon monoxide into a chamber containing the substrate and onto the surface layer; and after stopping the flowing of the carbon monoxide into the chamber and while maintaining the substrate at a temperature between 10 to 40 degrees Celsius, exposing the substrate to a plasma formed from an inert gas to reduce the oxidized metal.

In accordance with an embodiment of the present disclosure, a method for making a semiconductor device can include: receiving a substrate comprising an exposed surface, the exposed surface comprising a metal layer, where the metal layer includes a surface layer of oxidized metal; and performing, in a chamber containing the substrate, a cyclic surface preparation process, each cycle of the cyclic surface preparation process comprising flowing carbon monoxide into the chamber and onto the surface layer, after stopping the flowing of the carbon monoxide, flowing an inert gas into the chamber, igniting a plasma within the chamber, the plasma being generated from the inert gas, exposing the surface layer to the plasma, the exposing reducing the oxygen content in the surface layer, and after the exposing, stopping the power to the plasma and stopping the flow of the inert gas.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a cross-section view illustrating an intermediate structure during a method of making a semiconductor device according to an embodiment of the present disclosure;

FIG. 2 is an enlarged perspective view illustrating an oxidized metal layer during a method of making a semiconductor device according to an embodiment of the present disclosure, wherein FIG. 2 illustrates the surface after flowing carbon monoxide;

FIG. 3 is an enlarged perspective view illustrating an oxidized metal layer during a method of making a semiconductor device according to an embodiment of the present disclosure, wherein FIG. 3 illustrates the surface after exposing to an inert plasma;

FIG. 4 is a cross-section view illustrating an intermediate structure resulting after a method of making a semiconductor device according to an embodiment of the present disclosure;

FIG. 5 is a flow chart of a metal reduction process in accordance with an embodiment;

FIG. 6 is a flow chart of a metal reduction process in accordance with an embodiment;

FIG. 7 is a flow chart of a metal reduction process in accordance with an embodiment; and

FIG. 8 is a diagram illustrating a chamber of a plasma processing system for implementing methods of manufacturing semiconductor devices according to some embodiments of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure.

Some example embodiments of the present disclosure are described in more detail below with reference to the drawings of the present disclosure, to describe some example variations for some embodiments of the present disclosure. Other embodiments can also be understood from the entirety of the specification and the claims filed herein.

In the present disclosure, terms such as “first”, “second”, and the like, may be used to describe various components, but the components are not necessarily limited by such terms, for example, regarding nature, order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scope of rights according to the present disclosure.

In the present disclosure, certain elements may be discussed as, referred to, and actually plural, but only shown as a singular example in the drawings, even though that single example is among a set of a plurality. Similarly, certain elements may be discussed, referred to, and shown as singular, but may be plural or may be part of a set of a plurality of the same. Given that a structure and feature is typically repeated many times in a semiconductor device, one of ordinary skill in the art to which the present disclosure pertains can realize and understand such alternating between singular and plural.

Conventional processes for removing an oxidized metal surface layer from a top surface of a metal layer typically use a sputtering or etching with in a plasma containing hydrogen, and some processes involve high temperatures (e.g., greater than 200 degrees Celsius). Using hydrogen for removing oxygen from an exposed metal surface that has oxidized works well for situations in which the oxidized metal layer is more than about three monolayers in thickness because the hydrogen can deeply penetrate the surface. However, some hydrogen can remain stuck deeply into the metal layer or react with the metal layer, which can create defects in the metal layer and which can be undesirable because pure metal is more preferred for lower electrical resistance. Also, processes that use high temperatures to remove the oxidized metal layer can greatly consume thermal budget in the overall process flow, or may not be allowable for some process flows. Hence, there is a need for alternative options for removing an oxidized metal layer and/or for reducing/removing the oxide in the oxidized metal layer and leaving behind non-oxidized metal.

Embodiment of this disclosure provide a plasma enhanced reduction chemistry to reduce metal oxide surface layers to metallic layers. Advantageously, embodiments may be applied to removing surface oxide layers, e.g., monolayers of oxides, without consuming thermal budget, while not causing roughness to the surface, and with little or no metal sputtering that could contaminate a chamber.

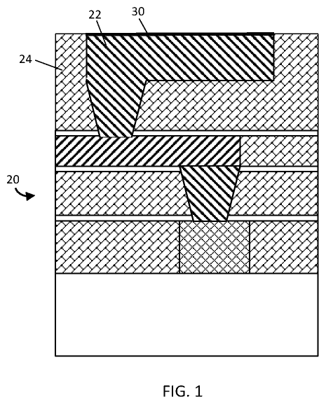

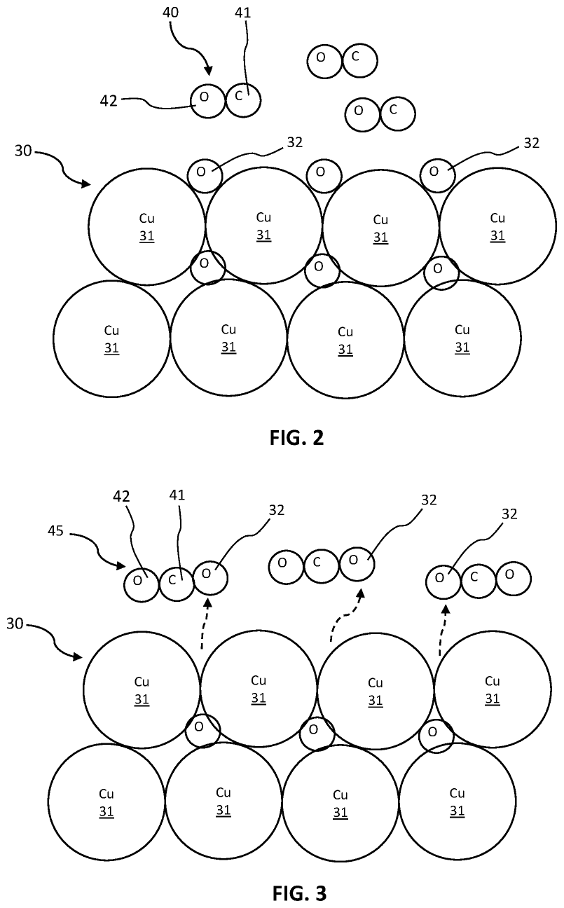

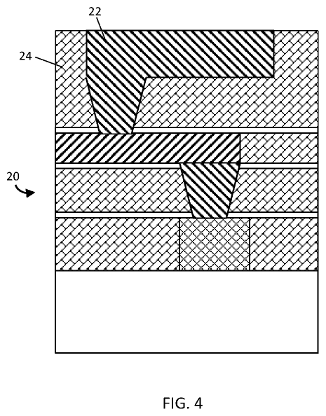

FIG. 1 is a cross-section view illustrating an intermediate structure during a method of making a semiconductor device according to an embodiment of the present disclosure. FIGS. 2-3 illustrate an enlarged perspective view illustrating an oxidized metal layer during a method of making a semiconductor device according to an embodiment of the present disclosure. FIG. 4 is a cross-section view illustrating an intermediate structure resulting after a method of making a semiconductor device according to an embodiment of the present disclosure.

For simplification and illustration purposes, FIGS. 1 and 4 are merely showing some portions of a substrate and of intermediate structures for a semiconductor device that can be relevant to a method of making a semiconductor device according to some embodiments of the present disclosure. Accordingly, in FIGS. 1 and 4, to simplify the drawings, as can be readily understood by one of ordinary skill in the pertinent art, additional layers and structures for a semiconductor device made before, under, below, or adjacent the intermediate structures shown in the drawings can be omitted and not shown. And accordingly, in FIGS. 1 and 4, to simplify the drawings, as can be readily understood by one of ordinary skill in the pertinent art, additional layers and structures for a semiconductor device made after, over, above, or adjacent the intermediate structures shown in the drawings can be omitted and not shown. Furthermore, in an actual completed semiconductor device cross-section, the intermediate structures, or remnants thereof, that are illustrated and represented in the drawings of the present disclosure in a simplified manner as having squared edges, rectangular block shapes, and/or linear shapes can be actually pointed (e.g., bottoms of the holes), more rounded, more curved shaped, and less linear shaped.

FIGS. 1 and 4 are various views of various intermediate structures of an example semiconductor device, schematically showing a processing sequence for forming the intermediate structures of the example semiconductor device using methods according to some embodiments of the present disclosure. In FIGS. 1 and 4, the example semiconductor device being built includes a dual damascene conductive trench and via structure formed and being prepared for subsequent processing operations in a back-end-of-line (BEOL) process flow. However, because metal features that can become oxidized (and for which a process flow can specify or require removal of such oxidation before proceeding to further processing operations) can be used in many different parts and stages of manufacturing a semiconductor device (including front-end-of-line (FEOL), middle-of-line (MOL), and BEOL), some embodiments of the present disclosure can be applied to making other types or portions of intermediate structures for other types and kinds of semiconductor devices (i.e., not necessarily limited to BEOL and not limited to dual damascene structures).

More specifically, referring to FIG. 1, an intermediate structure of a substrate 20 can include a metal layer 22 formed in a dielectric layer 24 using a dual damascene process during BEOL processing for making a semiconductor device for an integrated circuit. In FIG. 1, the intermediate structure can be after a chemical mechanical polishing or planarization (CMP) processing operation, such as removing excess material formed on top of the dielectric layer 24 during the forming or deposition of the metal layer 22, for example. In various embodiments, the substrate 20 may have been planarized such that the top surfaces of the metal layer 22 and the dielectric layer 24 are in a same horizontal plane.

In certain embodiments, the planarization may utilize a CMP process, followed by a cleaning process to remove impurities after the CMP process. Such cleaning processing after the CMP may use chemicals that contain oxygen, such cleaning can be performed in an environment that contains oxygen (e.g., ambient air), such cleaning can include a drying operation in an environment that contains oxygen (e.g., ambient air), or any combination thereof, for example. In such cases, the metal layer 22 can become oxidized, thereby forming a thin surface layer of oxidized metal on the exposed surfaces of the metal layer 22, which is illustrated schematically as a surface layer 30 of oxidized metal in FIG. 1. In some embodiments, the surface layer 30 of oxidized metal can also form or additionally form during other operations, such as loading a wafer into a carrier, transporting the wafer, waiting in queue while a wafer is in a carrier, loading a wafer into a tool or machine, loading a wafer into a chamber, or any combination thereof, for example. In such cases, even though the handling of the wafer is performed in a very controlled manner taking precautions to avoid or prevent oxidation of the exposed surfaces of the metal layer 22, a surface layer 30 of oxidized metal can still form rapidly and easily on a scale of one to five monolayers in thickness, for example.

As the sizing scale and voltage levels continue to decrease with the progressive development and advances in semiconductor manufacturing and semiconductor devices, even a few monolayers of oxidized metal left at a joining or an interface between conductors can become more critical, or unacceptable for quality standards, in affecting the performance and reliability of the semiconductor device (e.g., due to increases in resistance and/or parasitic capacitance, even though small, caused by a remaining oxidized metal portion). Accordingly, some embodiments of the present disclosure can provide a method of oxide reduction or removal of oxygen from an oxidized metal surface layer. A metal layer of an embodiment can be any metal that is susceptible to being oxidized and for which there can be a need or processing specification to reduce or remove oxidized metal from a surface, including but not necessarily limited to copper (Cu), cobalt (Co), ruthenium (Ru), molybdenum (Mo), tungsten (W), titanium (Ti), aluminum (Al), silver (Ag), nickel (Ni), tantalum (Ta), and niobium (Nb), for example.

In some embodiments, although not specifically illustrated in FIGS. 1 and 4 for example, one or more barrier/liner layers may be interposed between the dielectric layer 24 and the metal layer 22 to prevent diffusion and improve the isolation of the metal layer 22. For example, in some embodiments, the metal layer 22 in FIGS. 1 and 4 can contain copper (Cu), which would typically incorporate such barrier/liner layer(s), but are not shown in FIGS. 1 and 4 for purposes of simplifying the drawings. On the other hand, in some embodiments, the metal layer 22 can contain ruthenium (Ru), for example, which does not necessarily require the use of such barrier/liner layer(s) between the metal layer 22 and the dielectric layer 24.

In FIGS. 1 to 4, as an example embodiment and for purposes of an illustrative discussion, the metal layer 22 contains copper, and the surface layer 30 of oxidized metal contains copper oxide (Cu₂O and/or CuO). FIGS. 2-3 illustrate an enlarged perspective view of the surface layer 30 of FIG. 1, showing two monolayers of copper oxide. More specifically, FIG. 2 illustrates that the copper oxide includes copper 31 and oxygen 32.

Next, a method of reducing oxide or removing oxygen from a surface layer of oxidized metal according to some embodiments of the present disclosure will be described, using the surface layer 30 of FIGS. 1 and 2 containing copper oxide as an example for illustrative purposes. More specifically, computer simulation using copper oxide were performed by the inventor to simulate a method according to an embodiment of the present disclosure, which revealed successful oxide reduction by removal of oxygen from an exposed surface layer of copper oxide having a thickness of three monolayers.

The substrate 20 of FIG. 1 can be loaded into a chamber of a plasma processing system. Referring to FIG. 2, a first gas containing carbon monoxide 40 can be flowed into the chamber and onto the surface layer 30. More specifically, FIG. 2 illustrates that the carbon monoxide 40 includes carbon 41 and oxygen 42.

While flowing the carbon monoxide 40 into the chamber, the chamber can be at room temperature, or whatever temperature the chamber would be at in a fabrication facility without specifically heating the chamber for the purpose of increasing the temperature in the chamber, such as less than 40 degrees Celsius, or such as in a temperature range of 10 to 28 degrees Celsius, with some margin of about plus or minus 2-3 degrees Celsius on each side of that range, for example. In some implementations, the chamber may be partially cooled and hence may be between 0 and 28 degree Celsius. In some embodiments, the operation of flowing of the carbon monoxide 40 into the chamber can be performed at a substantially same substrate temperature or within a same range of substrate temperature. For example, the substrate temperature can be about room temperature. For example, the same range of substrate temperature can be from 10 to 28 degrees Celsius, with some margin of about plus or minus 2-3 degrees Celsius on each side of that range.

The carbon monoxide 40 may be flown at high pressure such that some of the carbon monoxide 40 gets adsorbed on the surface layer 30. The flow of carbon monoxide 40 may be stopped.

Referring to FIG. 3, after flowing the carbon monoxide 40 into a chamber, the carbon monoxide 40 can be reacted with the oxidized metal of the surface layer 30 (i.e., the copper oxide containing copper 31 and oxygen 32 in this example) to form carbon dioxide 45 and non-oxidized metal at the surface layer 30 by removing oxygen 32 from the oxidized metal of the surface layer 30. More specifically, FIG. 3 illustrates that the carbon dioxide 45 includes carbon 41 and oxygen 42 originally from the carbon monoxide 40, plus the oxygen 32 removed from the surface layer 30.

To assist in the oxide reduction or removal of oxygen from oxidized metal of the surface layer by the carbon monoxide to form carbon dioxide, the surface layer 30 is exposed to a plasma, e.g., formed from an inert gas chemistry. For the plasma assisting during the oxide reduction reaction, a noble gas can be flowed into the chamber. The electric field within the plasma can accelerate ions of the noble gas to the surface layer 30. The ion bombardment may generate localized heat at the surface layer and providing the energy for the metal oxide reduction reaction. Because the generated heating is localized, the underlying sensitive layers are not heated and the risk of damaging other layers is minimized.

The reaction is schematically illustrated in FIGS. 2-3, which shows the oxygen 32 is disassociated from the copper 31 to then bond with the carbon 41 of the carbon monoxide 40 to form carbon dioxide 45.

In some embodiments, the reacting operation for oxide reduction can be performed without adding heat to the chamber. As described above, some very localized heating will occur on the surface layer due to the bombardment of gases and/or ions, but otherwise other heating operations can be omitted. Thus, during the reacting operation for oxide reduction, the chamber can be at room temperature, or whatever temperature the chamber would be at in a fabrication facility without specifically heating the chamber for the purpose of increasing the temperature in the chamber, such as less than 40 degrees Celsius, or such as in a temperature range of 10 to 28 degrees Celsius, with some margin of about plus or minus 2-3 degrees Celsius on each side of that range, for example. In some embodiments, the operation of reacting for oxide reduction can be performed at a substantially same substrate temperature or within a same range of substrate temperature. For example, the substrate temperature can be about room temperature. For example, the same range of substrate temperature can be from 10 to 28 degrees Celsius, with some margin of about plus or minus 2-3 degrees Celsius on each side of that range. An advantage of using some embodiments of the present disclosure can be providing a single temperature process for process stability, such as at room temperature (i.e., no extra heating or thermal budget required in the process flow).

According to computer simulations, the change of energy (ΔE) during a reacting operation for oxide reduction, according to an embodiment of the present disclosure, using copper oxide (for example) can be −1.3 eV per oxygen removed from the surface layer 30. This simulation result confirms that there can be enough difference in the affinity for the oxygen 32 to bond to the carbon 41 of the carbon monoxide 40 to form carbon dioxide 45 compared to the affinity of the oxygen 32 to remain bonded with the copper 31, that an oxide reduction reaction can occur under such conditions. Similar simulations or experiments can be performed using other metal oxides to determine whether and to what extent a method according to an embodiment of the present disclosure can be used for a given metal substance, based on the affinity of the oxygen to bond with carbon relative to the metal substance.

Parameters of the operations can be varied to accommodate a given metal substance (or group of metal substances) selected for the metal layer 22. For example, to tune a method according to an embodiment of the present disclosure, the volumetric flow rate and/or flow timing of the carbon monoxide can be varied, the volumetric flow rate and/or flow timing of the noble gas can be varied, the overall pressure in the chamber can be varied, the electric power and/or radio frequency for generating the electric field and the plasma can be varied, the cycle times can be varied, and any combination thereof. In some embodiments, a first flow rate range for the flowing of the carbon monoxide can be in a range from 1 to 2000 sccm. In some embodiments, a second flow rate range for the flowing of the noble gas can be in a range from 1 to 500 sccm. In some embodiments, a pressure of the noble gas in the chamber while generating the electric field and the plasma can be in a range from 0.025 to 0.5 torr. In some embodiments, a power range for the generating of the electric field can be from 50 to 500 watts, e.g., 100 to 200 watts in one implementation. In some embodiments, a radio frequency range for the generating of the electric field can be from 13.56 to 300 MHz, e.g., 30 MHz to 100 MHz in one implementation. Due to use of relatively lower temperature in a method for some embodiments (e.g., closer to room temperature), conditions in the chamber can be compensated by adjusting the pressure in the chamber. As an example, for copper oxide, the parameters of the operations in a method according to an embodiment of the present disclosure can include a chamber pressure of about 50 mtorr using argon gas and a power of about 100 watts at a radio frequency of about 30 MHz for generating the electric field and the plasma in the chamber during the reacting operation.

In some embodiments, the electric field and plasma levels (and other tunable parameters of the plasma processing chamber) can be low enough that the carbon monoxide is not ionized. In some embodiments, the electric field and plasma levels (and other tunable parameters of the plasma processing chamber) can be set so that part of the carbon monoxide is not ionized (remaining intact as carbon monoxide) and part of the carbon monoxide is dissociated to carbon and oxygen ions by the plasma, which can be also accelerated toward the surface layer using the electric field. Also, by adjusting the electric field and plasma levels (and other tunable parameters of the plasma processing chamber) (e.g., such that most of or all of the carbon monoxide and noble gas do not penetrate or do not deeply penetrate the surface), the oxide reduction reaction process can be gentle and reduce side effects of roughness caused by sputtering with the noble gas, for example. Thus, because hydrogen can penetrate much deeper than carbon monoxide in some processes, using a method according to an embodiment of the present disclosure can provide a more gentle oxide reduction process than a conventional process using hydrogen, for example. Accordingly, a method of using carbon monoxide for oxide reduction according to an embodiment of the present disclosure can be an alternative to using hydrogen, and/or can supplement another oxide reduction process or cleaning process.

Bombarding the surface layer harder and deeper with the carbon monoxide using a larger electric field power level can cause some of the carbon monoxide to remain stuck in the metal layer, but this might not have noticeable or significant negative effects on the electrical characteristics of the metal layer. Also, bombarding the surface layer with the carbon monoxide, the noble gas, and/or ions thereof, at too much acceleration using a larger electric field power level can create roughness on the surface and/or sputtering away metal or metal oxide, which can contaminate the chamber. Thus, when applying a method embodiment, the parameters of the processes can be tuned to provide sufficient oxide reduction while preventing roughness resulting on the surface of the metal layer. Also, if the electrical field power levels are kept sufficiently low, sputtering of the metal and/or metal oxide can be prevented or minimal so that the chamber is not contaminated with metal and/or metal oxide from the process.

While flowing the carbon monoxide into the chamber, the carbon monoxide can saturate the chamber. In some embodiments, the flowing of the carbon monoxide into the chamber can be stopped prior to the pressurizing of the chamber with the noble gas and generating the electric field and plasma, and the flowing of the carbon monoxide can be without plasma, such that those operations are separate. In some embodiments, the flowing of the carbon monoxide into the chamber can be stopped shortly after beginning the pressurizing of the chamber with the noble gas and generating the electric field and plasma, such that those operations overlap. In some embodiments, the flowing of the carbon monoxide into the chamber can continue during part or all of the pressurizing of the chamber with the noble gas and generating the electric field and plasma, such that those operations overlap. In some embodiments, the flowing of the carbon monoxide into the chamber can be started at the same time as or shortly after beginning the pressurizing of the chamber with the noble gas and/or generating the electric field and plasma, such that those operations are simultaneous or substantially overlapping. In some embodiments, the flowing of the carbon monoxide into the chamber can be at a first volumetric flow rate before beginning the pressurizing of the chamber with the noble gas and generating the electric field and plasma, and then the flowing of carbon monoxide into the chamber can be at a second volumetric flow rate after beginning the pressurizing of the chamber with the noble gas and generating the electric field and plasma, such that the first and second volumetric flow rates of the carbon monoxide are different, and such that those operations are overlapping.

In some embodiments, regardless of the timing of the flowing of the carbon monoxide relative to the use of the noble gas, electric field, and plasma, it can be preferred to saturate the chamber with carbon monoxide, and to maintain a saturation of the carbon monoxide in the chamber, which can depend upon other parameters and settings for the use of the noble gas, electric field, and plasma during the reaction.

At some point during a method according to some embodiments of the present disclosure, at least part of the carbon monoxide, the carbon dioxide, and the noble gas can be removed from the chamber. In some embodiments, the removing of the carbon monoxide, the carbon dioxide, and the noble gas can be performed after the generating the electric field and plasma. In some embodiments, the removing of the carbon monoxide, the carbon dioxide, and the noble gas can begin or can be performed during the generating the electric field and plasma. In some embodiments, there can be a sequence of flowing of the carbon monoxide, optionally stopping the flowing of the carbon monoxide, then reacting while generating the electric field and plasma, and then removing at least part of the carbon monoxide, the carbon dioxide, and the noble gas from the chamber.

In some embodiments, the flowing of the carbon monoxide and the reacting while generating the electric field and plasma can be sequentially repeated, and cycled one or more times, as needed or as specified in a given process flow to sufficiently remove oxygen from the oxidized metal in the surface layer 30. In some embodiments, there can be a sequence of flowing of the carbon monoxide, then reacting while generating the electric field and plasma, then removing at least part of the carbon monoxide, the carbon dioxide, and the noble gas from the chamber, and then sequentially repeating the flowing, the reacting, and the removing, in one or more cycles.

FIG. 4 is a cross-section view illustrating an intermediate structure resulting after a method of making a semiconductor device according to an embodiment of the present disclosure. Accordingly, the surface layer 30 of oxidized metal of FIG. 1 can be converted back to non-oxidized metal (or substantially non-oxidized metal, or mostly non-oxidized metal), as illustrated in FIGS. 2-3, resulting in the intermediate structure shown in FIG. 4.

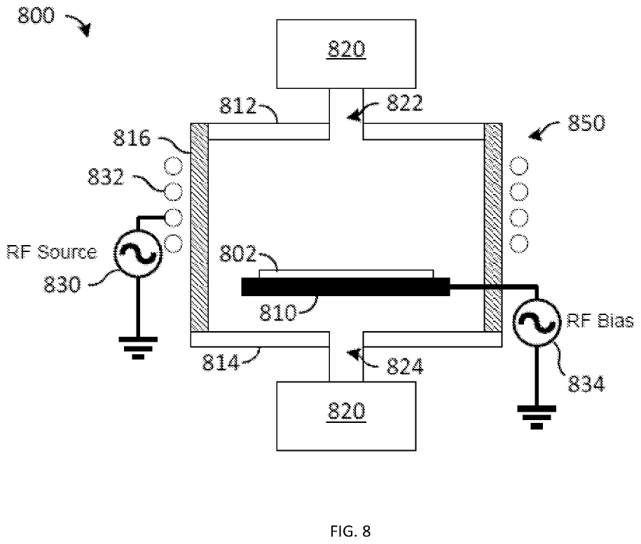

In some embodiments, a substrate having a surface layer 30 of oxidized metal on a metal layer 22 can be introduced in a plasma processing chamber containing an inductively coupled plasma (ICP) source. An example plasma processing chamber containing an ICP source is schematically shown below in FIG. 8.

In some embodiments, a wafer can be positioned on a wafer holder that is electrically biased, and thereby can provide sequential anisotropic exposures of the surface layer 30 to the plasma-excited gases of carbon monoxide and noble gas (and/or some ions thereof). The anisotropic exposure can be predominantly in a vertical direction (e.g., perpendicular to a wafer surface), but other angles and/or varying angles are possible also for some embodiments. In some embodiments, the wafer holder can be electrically biased (for providing anisotropic plasma exposure) or not electrically biased (for allowing isotropic plasma exposure), or varying between, during the process operations.

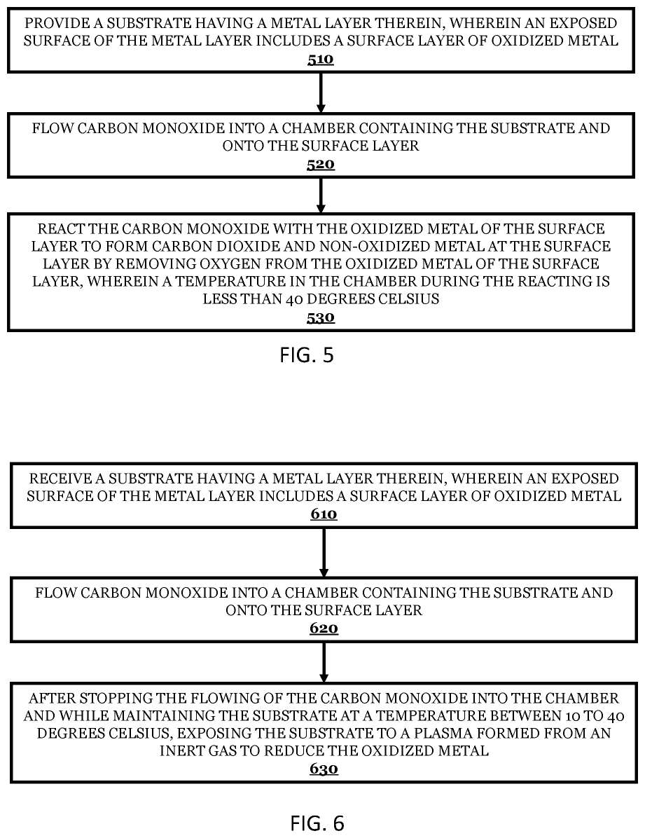

FIG. 5 illustrates a flow chart implementing the metal reduction in accordance with an embodiment.

In an embodiment, a method includes providing a substrate having a metal layer therein, where an exposed surface of the metal layer includes a surface layer of oxidized metal (box 510). The method includes flowing carbon monoxide into a chamber containing the substrate and onto the surface layer (box 520). The method includes reacting the carbon monoxide with the oxidized metal of the surface layer to form carbon dioxide and non-oxidized metal at the surface layer by removing oxygen from the oxidized metal of the surface layer, where a temperature in the chamber during the reacting is less than 40 degrees Celsius (box 530).

FIG. 6 illustrates a flow chart implementing the metal reduction in accordance with an embodiment.

In an embodiment, a method includes receiving a substrate having a metal layer therein, where an exposed surface of the metal layer includes a surface layer of oxidized metal (box 610). The method includes flowing carbon monoxide into a chamber containing the substrate and onto the surface layer (box 620). After stopping the flowing of the carbon monoxide into the chamber and while maintaining the substrate at a temperature between 10 to 40 degrees Celsius, the substrate is exposed to a plasma formed from an inert gas to reduce the oxidized metal (box 630).

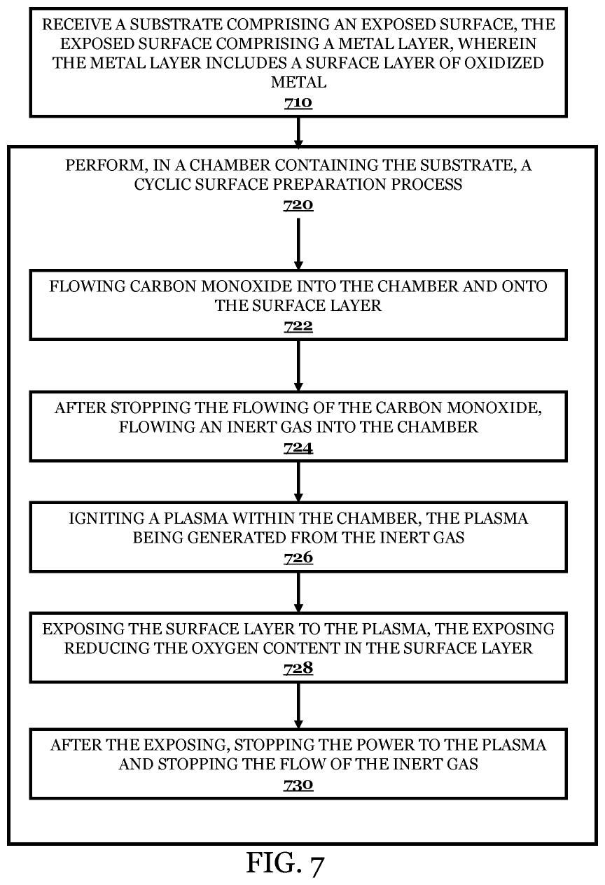

FIG. 7 illustrates a flow chart implementing the metal reduction in accordance with an embodiment.

A method for making a semiconductor device includes receiving a substrate comprising an exposed surface (box 710), the exposed surface comprising a metal layer, where the metal layer includes a surface layer of oxidized metal. The substrate can be subjected to a cyclic surface preparation process (box 720). Each cycle of the cyclic surface preparation process includes flowing carbon monoxide into the chamber and onto the surface layer (box 722), after stopping the flowing of the carbon monoxide, flowing an inert gas into the chamber (box 724), igniting a plasma within the chamber, the plasma being generated from the inert gas (box 726), exposing the surface layer to the plasma (box 728), the exposing reducing the oxygen content in the surface layer, and after the exposing, stopping the power to the plasma and stopping the flow of the inert gas (box 730).

The embodiments described in FIGS. 5-7 may be implemented as further described using FIGS. 1-3, 8.

FIG. 8 is a diagram illustrating a chamber of a plasma processing system 800 that can be used in implementing methods of manufacturing semiconductor devices according to some embodiments of the present disclosure. The plasma processing system 800 can be used for performing electrical field and plasma processes, such as assisting the reaction using an electric field and/or plasma, as well as providing the flowing and removing of gases in the chamber 850, for example. The plasma processing system 800 can have a plasma processing chamber 850 configured to sustain plasma directly above a wafer 802 loaded onto a wafer holder 810. A process gas can be introduced to the plasma processing chamber 850 through a gas inlet 822 and can be pumped out of the plasma processing chamber 850 through a gas outlet 824. The gas inlet 822 and the gas outlet 824 may include a set of multiple gas inlets and gas outlets, respectively. The gas flow rates and chamber pressure can be controlled by a gas flow control system 820 coupled to the gas inlet 822 and the gas outlet 824. The gas flow control system 820 can include various components, such as high-pressure gas canisters, valves (e.g., throttle valves), pressure sensors, gas flow sensors, vacuum pumps, pipes, and electronically programmable controllers, for example. A radio frequency (RF) bias power source 834 and an RF source power source 830 can be coupled to respective electrodes of the plasma processing chamber 850. The wafer holder 810 can also be the electrode coupled to the RF bias power source 834 (e.g., for providing an electrically-biased wafer holder). In various embodiments, the plasma may be powered to be inductively coupled, capacitively coupled, or a hybrid. In an implementation, the RF source power source 830 can be coupled to a helical electrode 832 coiled around a dielectric sidewall 816. In another implementation, the electrode 832 can be placed in other locations such as over the top plate 812 and within the chamber in different combinations. The gas inlet 822 can be an opening in a top plate 812. The gas outlet 824 can be an opening in a bottom plate 814. The top plate 812 and bottom plate 814 can be conductive and electrically connected to the system ground (a reference potential).

The plasma processing system 800 is an example only. In various alternative embodiments, the plasma processing system 800 can be configured to sustain inductively coupled plasma (ICP) with RF source power coupled to a planar coil over a top dielectric cover, or capacitively coupled plasma (CCP) sustained using a disc-shaped top electrode in the plasma processing chamber 850. Alternately, other suitable configurations such as electron cyclotron resonance (ECR) plasma sources and/or a helical resonator can be used. The RF bias power source 834 can be used to supply continuous wave (CW) or pulsed RF power to sustain the plasma. According to some embodiments, the RF bias power source 834 may not be powered so that the wafer holder 810 is not electrically biased. Gas inlets and gas outlets can be coupled to sidewalls of the plasma processing chamber, and pulsed RF power sources and pulsed DC power sources also can be used in some embodiments. In various embodiments, the RF power, chamber pressure, substrate temperature, gas flow rates and other plasma process parameters can be selected in accordance with respective process recipes. For some embodiments, a remote plasma system and/or a batch system may be used. For example, the wafer holder can be configured to support a plurality of wafers that are spun around a central axis as they pass through different plasma zones.

More example embodiments of the present disclosure are summarized here. Other embodiments can also be understood from the entirety of the specification as well as the claims filed herein.

Example 1. A method for making a semiconductor device, the method comprising: providing a substrate having a metal layer therein, where an exposed surface of the metal layer includes a surface layer of oxidized metal; flowing carbon monoxide into a chamber containing the substrate and onto the surface layer; and reacting the carbon monoxide with the oxidized metal of the surface layer to form carbon dioxide and non-oxidized metal at the surface layer by removing oxygen from the oxidized metal of the surface layer, where a temperature in the chamber during the reacting is less than 40 degrees Celsius.

Example 2. The method of example 1, where the reacting comprises: flowing a noble gas into the chamber; generating a plasma from the noble gas in the chamber; and exposing the surface layer to the plasma to reduce the oxidized metal of the surface layer.

Example 3. The method of one of examples 1 to 2, further comprising removing at least part of the carbon monoxide, the carbon dioxide, and the noble gas from the chamber.

Example 4. The method of one of examples 1 to 3, further comprising sequentially repeating the flowing of the carbon monoxide and the reacting.

Example 5. The method of one of examples 1 to 4, where the temperature in the chamber during the reacting is in a temperature range from 0 to 28 degrees Celsius, where generating the plasma comprises providing radio frequency (RF) power to an electrode of the plasma chamber, the RF power being in a power range between 50 and 500 watts, where the RF power having a radio frequency range of 13.56 MHz to 300 MHz, where a first flow rate range for the flowing of the carbon monoxide is 1 to 2000 sccm, and where a second flow rate range for the flowing of the noble gas is 1 to 500 sccm.

Example 6. The method of one of examples 1 to 5, where the noble gas comprises one of or any combination of argon, helium, neon, krypton, and xenon.

Example 7. The method of one of examples 1 to 6, where the metal layer contains copper, and where the noble gas contains argon.

Example 8. The method of one of examples 1 to 7, further comprising removing at least part of the carbon monoxide and the carbon dioxide from the chamber.

Example 9. The method of one of examples 1 to 8, further comprising, after the removing, sequentially repeating the flowing of the carbon monoxide, the reacting, and the removing.

Example 10. The method of one of examples 1 to 9, where the surface layer of the oxidized metal has a thickness of three monolayers or less.

Example 11. The method of one of examples 1 to 10, where the temperature in the chamber during the reacting is in a range from 10 to 28 degrees Celsius.

Example 12. The method of one of examples 1 to 11, where the metal layer comprises one of or any combination of copper, cobalt, ruthenium, molybdenum, and tungsten.

Example 13. A method for making a semiconductor device, the method comprising: receiving a substrate having a metal layer therein, where an exposed surface of the metal layer includes a surface layer of oxidized metal; flowing carbon monoxide into a chamber containing the substrate and onto the surface layer; and after stopping the flowing of the carbon monoxide into the chamber and while maintaining the substrate at a temperature between 10 to 40 degrees Celsius, exposing the substrate to a plasma formed from an inert gas to reduce the oxidized metal.

Example 14. The method of example 13, where the plasma is a remote plasma.

Example 15. The method of one of examples 13 to 14, where the plasma is generated in the chamber.

Example 16. The method of one of examples 13 to 15, where reducing the oxidized metal comprises reacting the carbon monoxide with the oxidized metal of the surface layer to form carbon dioxide and non-oxidized metal at the surface layer by removing oxygen from the oxidized metal of the surface layer.

Example 17. The method of one of examples 13 to 16, where exposing the substrate to the plasma comprises: flowing a noble gas into the chamber; generating the plasma in the chamber; and accelerating ions of the noble gas to the surface layer.

Example 18. The method of one of examples 13 to 17, further comprising sequentially repeating the flowing of the carbon monoxide and the exposing to the plasma.

Example 19. The method of one of examples 13 to 18, where the surface layer of the oxidized metal has a thickness of three monolayers or less; where the metal layer comprises one of or any combination of copper, cobalt, ruthenium, molybdenum, and tungsten; and where the noble gas comprises one of or any combination of argon, helium, neon, krypton, and xenon.

Example 20. The method of one of examples 13 to 19, where the metal layer contains copper, where the noble gas contains argon, and where the temperature in the chamber during the reacting is in a range from 10 to 28 degrees Celsius.

Example 21. A method for making a semiconductor device, the method comprising: receiving a substrate comprising an exposed surface, the exposed surface comprising a metal layer, where the metal layer includes a surface layer of oxidized metal; and performing, in a chamber containing the substrate, a cyclic surface preparation process, each cycle of the cyclic surface preparation process comprising flowing carbon monoxide into the chamber and onto the surface layer, after stopping the flowing of the carbon monoxide, flowing an inert gas into the chamber, igniting a plasma within the chamber, the plasma being generated from the inert gas, exposing the surface layer to the plasma, the exposing reducing the oxygen content in the surface layer, and after the exposing, stopping the power to the plasma and stopping the flow of the inert gas.

Example 22. The method of example 21, where the exposing comprises reacting the carbon monoxide with the oxidized metal of the surface layer to form carbon dioxide and non-oxidized metal at the surface layer by removing oxygen from the oxidized metal of the surface layer.

Example 23. The method of one of examples 21 to 22, where the plasma is generated by powering an electrode of the chamber with radio frequency (RF) power of 50 to 500 Watts at a frequency of 30 MHz to 100 MHZ.

Example 24. The method of one of examples 21 to 23, where the metal layer comprises one of or any combination of copper, cobalt, ruthenium, molybdenum, and tungsten; and where the noble gas comprises one of or any combination of argon, helium, neon, krypton, and xenon.

Example 25. The method of one of examples 21 to 24, where the surface layer of the oxidized metal has a thickness of three monolayers or less, where the metal layer contains copper, where the noble gas contains argon, and where the temperature in the chamber during the reacting is in a range from 10 to 30 degrees Celsius.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for making a semiconductor device, the method comprising:
providing a substrate having a metal layer therein, wherein an exposed surface of the metal layer includes a surface layer of oxidized metal;
flowing carbon monoxide into a chamber containing the substrate and onto the surface layer; and
reacting the carbon monoxide with the oxidized metal of the surface layer to form carbon dioxide and non-oxidized metal at the surface layer by removing oxygen from the oxidized metal of the surface layer, wherein a temperature in the chamber during the reacting is less than 40 degrees Celsius.

2. The method of claim 1, wherein the reacting comprises:
flowing a noble gas into the chamber;
generating a plasma from the noble gas in the chamber; and
exposing the surface layer to the plasma to reduce the oxidized metal of the surface layer.

3. The method of claim 2, further comprising removing at least part of the carbon monoxide, the carbon dioxide, and the noble gas from the chamber.

4. The method of claim 3, further comprising sequentially repeating the flowing of the carbon monoxide and the reacting.

5. The method of claim 2, wherein the temperature in the chamber during the reacting is in a temperature range from 0 to 28 degrees Celsius;
wherein generating the plasma comprises providing radio frequency (RF) power to an electrode of the plasma chamber, the RF power being in a power range between 50 and 500 watts;
wherein the RF power having a radio frequency range of 13.56 MHz to 300 MHZ;
wherein a first flow rate range for the flowing of the carbon monoxide is 1 to 2000 sccm; and
wherein a second flow rate range for the flowing of the noble gas is 1 to 500 sccm.

6. The method of claim 2, wherein the noble gas comprises one of or any combination of argon, helium, neon, krypton, and xenon.

7. The method of claim 2, wherein the metal layer contains copper, and wherein the noble gas contains argon.

8. The method of claim 1, further comprising removing at least part of the carbon monoxide and the carbon dioxide from the chamber.

9. The method of claim 8, further comprising, after the removing, sequentially repeating the flowing of the carbon monoxide, the reacting, and the removing.

10. The method of claim 1, wherein the surface layer of the oxidized metal has a thickness of three monolayers or less.

11. The method of claim 1, wherein the temperature in the chamber during the reacting is in a range from 10 to 28 degrees Celsius.

12. The method of claim 1, wherein the metal layer comprises one of or any combination of copper, cobalt, ruthenium, molybdenum, and tungsten.

13. A method for making a semiconductor device, the method comprising:
receiving a substrate having a metal layer therein, wherein an exposed surface of the metal layer includes a surface layer of oxidized metal;
flowing carbon monoxide into a chamber containing the substrate and onto the surface layer; and
after stopping the flowing of the carbon monoxide into the chamber and while maintaining the substrate at a temperature between 10 to 40 degrees Celsius, exposing the substrate to a plasma formed from an inert gas to reduce the oxidized metal.

14. The method of claim 13, wherein the plasma is a remote plasma.

15. The method of claim 13, wherein the plasma is generated in the chamber.

16. The method of claim 13, wherein reducing the oxidized metal comprises reacting the carbon monoxide with the oxidized metal of the surface layer to form carbon dioxide and non-oxidized metal at the surface layer by removing oxygen from the oxidized metal of the surface layer.

17. The method of claim 13, wherein exposing the substrate to the plasma comprises:
flowing a noble gas into the chamber;
generating the plasma in the chamber; and
accelerating ions of the noble gas to the surface layer.

18. The method of claim 13, further comprising sequentially repeating the flowing of the carbon monoxide and the exposing to the plasma.

19. The method of claim 13, wherein the surface layer of the oxidized metal has a thickness of three monolayers or less;
wherein the metal layer comprises one of or any combination of copper, cobalt, ruthenium, molybdenum, and tungsten;
wherein the noble gas comprises one of or any combination of argon, helium, neon, krypton, and xenon; and
wherein the temperature in the chamber during the reacting is in a range from 10 to 28 degrees Celsius.

20. A method for making a semiconductor device, the method comprising:
receiving a substrate comprising an exposed surface, the exposed surface comprising a metal layer, wherein the metal layer includes a surface layer of oxidized metal; and
performing, in a chamber containing the substrate, a cyclic surface preparation process, each cycle of the cyclic surface preparation process comprising
flowing carbon monoxide into the chamber and onto the surface layer,
after stopping the flowing of the carbon monoxide, flowing an inert gas into the chamber,
igniting a plasma within the chamber, the plasma being generated from the inert gas,
exposing the surface layer to the plasma, the exposing reducing the oxygen content in the surface layer, and
after the exposing, stopping the power to the plasma and stopping the flow of the inert gas.

21. The method of claim 20, wherein the exposing comprises reacting the carbon monoxide with the oxidized metal of the surface layer to form carbon dioxide and non-oxidized metal at the surface layer by removing oxygen from the oxidized metal of the surface layer.

22. The method of claim 20, wherein the plasma is generated by powering an electrode of the chamber with radio frequency (RF) power of 50 to 500 Watts at a frequency of 30 MHz to 100 MHz;
wherein the surface layer of the oxidized metal has a thickness of three monolayers or less;
wherein the metal layer contains copper;
wherein the noble gas contains argon; and
wherein the temperature in the chamber during the reacting is in a range from 10 to 30 degrees Celsius.
